(19) United States
(12) Patent Application Publication
(10) Pub. No.: US 2012/0017436 A1
(43) Pub. Date: Jan. 26, 2012

(54) Selective encapsulation of electronic components

(76) Inventors: Kenneth E. Wing, Alpine, CA (US); Scott T. Carroll, Lakeside, CA (US)

(21) Appl. No.: 13/135,934

(22) Filed: Jul. 20, 2011

Related U.S. Application Data
(63) Continuation-in-part of application No. 11/659,544, filed on Feb. 6, 2007, now abandoned.

(51) Int. Cl. H05K 3/28

(52) U.S. Cl. 29/841

(57) ABSTRACT

A method for the selective encapsulation of electronic components on a printed circuit board comprising, in one embodiment, the steps of delivering the printed circuit board to an encapsulating nest at room temperature; damming the target areas with a dam resin having a latent curing agent and deposited in the shape of walls of predetermined heights, according to the desired fill heights; dispensing a fill resin to fill the dammed areas; and curing the dam and fill resins for a suitable amount of time. In a different embodiment, the invention comprises the additional steps of laying resin beads, each in a position corresponding to the footprint of each target component; and of positioning the target components over the beads and soldering the components.

### FIELD OF THE INVENTION

The present invention relates to a method for the selective encapsulation of electronic components. More particularly, the present invention relates to a method for the selective encapsulation of certain electronic components on a printed circuit board or portions thereof, within predefined perimeters and with resin layers of predetermined thicknesses.

### BACKGROUND OF THE INVENTION

Electronic components on printed circuit boards often require protection from a variety of threats. For instance, designers and manufacturers often need to protect electronic components from adverse physical and environmental impacts, such as shock, moisture, contamination, or abuse; from voltage differentials with neighboring components; or from “reverse engineering” by competitors seeking to copy proprietary designs.

To protect electronic components, some manufacturers employ an over-molding process that encases the electronic components in a plastic shell. Other manufacturers instead utilize a potting process that encapsulates the components in a resin, typically an epoxy resin.

Potting technology has evolved over time into two distinct manufacturing methods, “glob top” and “darn & fill.” With glob top, a certain amount of resin is deposited over the component to be protected. It is evident, however, that this process is relatively uncontrolled. The encapsulating resin creates a mound over the target component and generally does not provide a uniform encapsulation of the component. It is also very difficult to control precisely the perimeter within which the resin will reside. To compensate for the inherent imprecision of the glob top process, manufacturers tend to employ amounts of resin in excess of the nominal requirements, in order to insure that every portion of the target component will be coated with the minimum required amounts of resin.

Therefore, there is a need for an encapsulation process, wherein the protective resin is deposited in layers of relatively uniform thicknesses and is confined within predetermined perimeters.

Dam & fill instead is a two-step process, wherein a dam of high viscosity resin is deposited around the target component and is later filled with a lower viscosity resin, creating a dome-like layer that encases the component and the related wire bonds. A variety of resins can be employed for this process, typically epoxies with a base resin and a curing agent that are mixed in situ. Resins of higher viscosity are generally employed as dam resins, and resins of lower viscosity are employed as fill resins, in order to achieve proper flow from the dispensing equipment and a proper packing of all the interstices within the fill area, thereby minimizing entrapped air and void formation.

In the prior art, the encapsulating resins are stored at −40 C and thawed at ambient temperature for 30 to 45 minutes prior to use. Successively, both the encapsulating resins and the printed circuit boards (hereinafter, “PCBs”) are pre-heated, in order to maximize resin flow, and the PCBs are further subjected to contact heat during resin coating. The encapsulating resins in the prior art are then cured with heating cycles of extended duration, sometimes over 24 hours.

Thus, while the dam & fill process provides a more accurate resin placement than the glob top process, it also requires extended heat application to the board, which increases process costs and which may damage the electronic components. Further, the low viscosity of the heated fill resin may generate resin runoffs and hinder a precise positioning of the resin within narrowly defined areas of the board or on certain portions only of the components, making the dam & fill process suitable only for the encapsulation of extended portions of a PCB, rather than for the selective encapsulation of portions of individual components or of narrowly defined areas of the PCB. Still further, the low viscosity of the fill resin prevents the deposition of the fill resin in multiple layers, which would provide for different levels of protection for different components within the same dammed area.

Therefore, there is a need for a method for the selective encapsulation of electronic components that is simpler than the prior art and that provides for reduced process times, lower material requirements, and minimal heat exposure.

There is a further need for a method for the selective encapsulation of electronic components that enables a precise positioning of the resin over predetermined portions of the PCB or of individual components.

There is a still further need for a method for the selective encapsulation of electronic components wherein resin can be deposited in multiple layers over target components, providing for differential levels of protection for different components possible, as well as an increased density of board population.

### SUMMARY OF THE INVENTION

The present invention relates to a method for the selective encapsulation of electronic components on a PCB.

In one embodiment, the invention comprises the steps of delivering the PCB to an encapsulating nest at room temperature; damming the target areas with a dam resin deposited in the shape of walls of predetermined heights, according to the desired fill heights; dispensing a fill resin to fill the dammed areas; and curing the dam and fill resins for a short time period, typically 20 minutes.

In another embodiment, the invention comprises the steps of delivering a substrate to an encapsulating nest at room temperature; laying resin beads, typically in a transverse position in relation to the footprint of each target component; positioning the target components over the resin beads and soldering the components; damming the target areas with a dam resin deposited in the shape of walls of predetermined heights, according to the desired fill heights; dispensing a fill resin to fill the dammed areas; and curing the dam and fill resins for a short time period, typically approximately 20 minutes.

In still another embodiment, the invention comprises the step of positioning a resin bead between an electronic component on a PCB and the PCB substrate when encapsulating resins of any chemistries are employed, whether in a room temperature environment or not.

It is an advantage of the present invention to provide a simplified method for the encapsulation of electronic components, wherein process times are reduced, materials requirements are decreased, and heat exposure of the components is lowered in comparison with the prior art.

It is another advantage of the present invention to provide a method for the selective encapsulation of electronic components that enables both the precise positioning of the resin over the areas to be encapsulated and the encapsulations of different components with resin layers of different thicknesses.

Still another advantage of the present invention is to provide a method that enables designers and manufacturers of PCBs to reduce spacing between components and to increase component density on the boards.

These and other advantages of the present invention will become apparent from a reading of the following description, and may be realized by means of the instrumentalities and combinations particularly pointed out in the appended claims.

### BRIEF DESCRIPTION OF DRAWINGS

The drawings constitute a part of this specification and include exemplary embodiments of the invention, which may be embodied in various forms. It is to be understood that in some instances various aspects of the invention may be shown exaggerated or enlarged to facilitate an understanding of the invention.

FIG. 1A is a perspective view of a PCB after the practice of a first embodiment of the invention.

FIG. 1B is a plan view of the PCB illustrated in FIG. 1A.

FIG. 2 is a flow chart detailing the steps of the first embodiment of the invention.

FIG. 3A is a plan view of a portion of a PCB after the practice of a second embodiment of the invention.

FIG. 3B is a cross-sectional view of a detail of the PCB of FIG. 3A.

FIG. 3C is a perspective view of the portion of a PCB of FIG. 3A.

FIG. 4 is a plan view of a portion of the PCB of FIG. 3A illustrating the practice of the first two steps of the second embodiment of the invention.

FIG. 5A is a cross-sectional view of a detail of the PCB of FIG. 4, illustrating a first variant of the second step of the second embodiment of the invention.

FIG. 5B is a cross-sectional view of a detail of the PCB of FIG. 4, illustrating a second variant of the second step of the second embodiment of the invention.

FIG. 6 is a flow chart illustrating the steps of the second embodiment of the invention.

### DETAILED DESCRIPTION OF THE PREFERRED EMBODIMENTS

Detailed descriptions of embodiments of the invention are provided herein. It is to be understood, however, that the present invention may be embodied in various forms. Therefore, the specific details disclosed herein are not to be interpreted as limiting, but rather as a representative basis for teaching one skilled in the art how to employ the present invention in virtually any detailed system, structure, or manner.

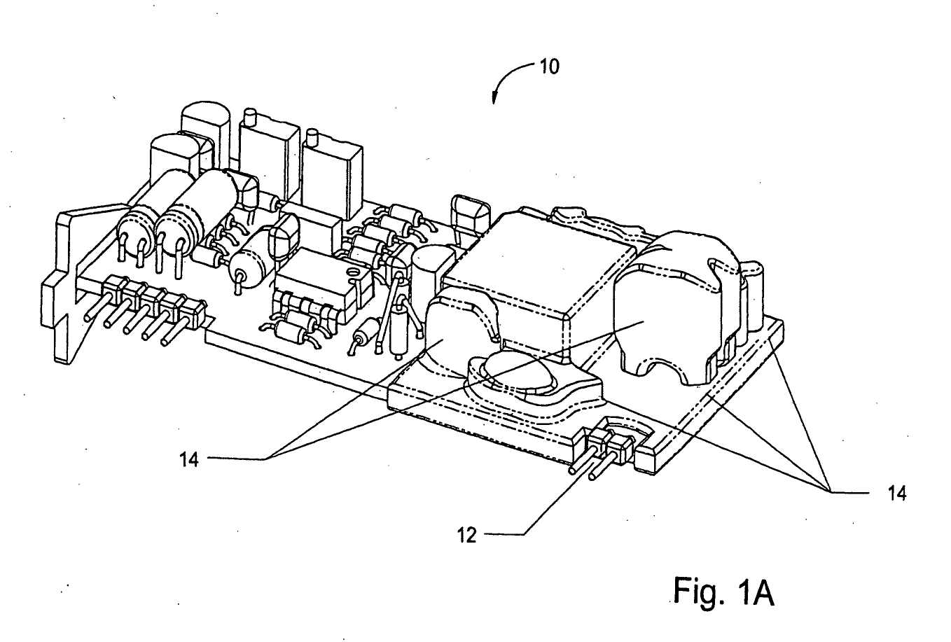

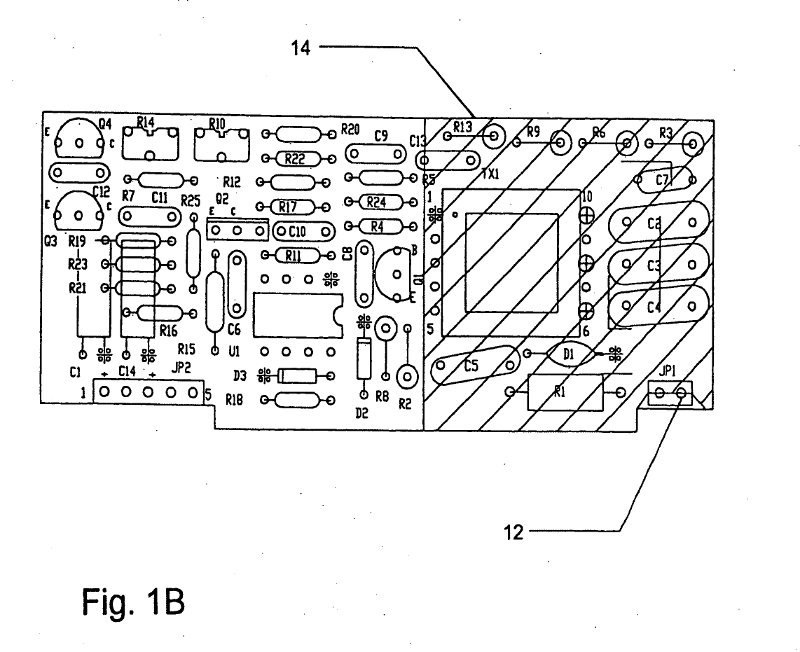

Turning first to FIGS. 1A and 1B, there is shown the practice of a first embodiment of the invention, as illustrated in a perspective view in FIG. 1A and in a plan view in FIG. 1B. By the practice of the first embodiment, a PCB manufacturer is enabled to process a circuit board that is completely non-encapsulated into a board having an encapsulated portion and a non-encapsulated portion. More specifically, the first embodiment enables a user to accurately calibrate the area or areas to be encapsulated, as well as the thicknesses of the encapsulating layer or layers. For instance, in a PCB 10 illustrated in FIGS. 1A (top side) and 1B (bottom side), the encapsulation was performed over only a portion of PCB 10, and a small area 12 surrounded by encapsulated portion was left non-encapsulated to leave the contact points exposed.

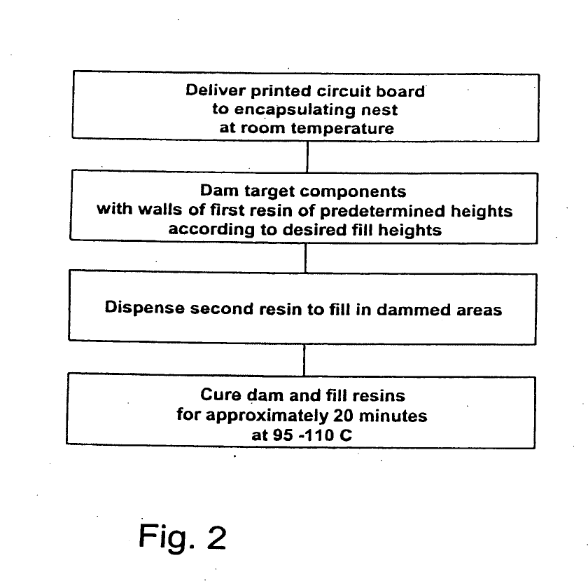

The steps comprised in the first embodiment of the invention are summarized in FIG. 2. In the first step, a PCB is delivered to an encapsulating nest in a room temperature environment, preferably with an automated delivery line.

In the second step, the target areas of the board are surrounded by a dam, which may encircle entire portions of the board, individual components on the board, or even portions of individual components, if it is desired to leave portions of certain components non-encapsulated after processing.

The dam comprises a resin (typically, an epoxy resin) of a thixotropy such to enable an easy yet accurate resin placement, and to maintain the resin in place during processing, thereby avoiding resin run-offs. The dam resin maybe a system of two chemical components that are mixed in situ, wherein one component is a base resin and the second component is a curing agent, or is preferably a pre-mixed resin delivered as a mono-component system. In either case, the curing agent in the present embodiment is “latent,” that is, is of such a chemical nature that does not essentially react at room temperature with the base resin. Examples of latent curing agents are, among others, amineimide compounds and amine compound/epoxy compound adducts. In our experiments, Resinlab W082498-18 resin (hereinafter, the “-18 resin”) was employed as a dam resin, which was delivered as a mono-component system and which was stored and dispensed at room temperature.

The dam resin may be applied in a room temperature environment manually, for instance, with a brush or with a small stick applicator; or, preferably, with an automated dispensing equipment capable of delivering the resin rapidly and precisely with a needle or with a spraying nozzle.

A plurality of dams may be deposited on the PCB, in order to encapsulate different portions of the PCB. Because different components may be of different sizes, or be positioned at different heights from the board, different dams may have walls of different heights, in order to achieve predetermined heights of the fill resin.

In the third step, the dammed areas are filled with a fill resin, of a chemistry compatible with the dam resin, so to achieve an appropriate bond between the two resins. In particular, the dam and fill resins may comprise curing agents of identical or different molecular structures, as long as the dam and fill resins are capable of bonding to each other and of curing with the same heating cycle. For instance, if the -18 resin is used as a dam resin, Resinlab W082498-13 (hereinafter, the “-resin”) may be employed as a fill resin.

The fill resin is preferably delivered pre-vacuumed, in order to minimize air entrapment in the encapsulation layer, and is also dispensed in a room temperature environment either manual by casting, brushing, or with a small stick applicator; or, preferably, with automated dispensing equipment.

The fill resin can be applied in a single layer or in successive layers up to predetermined heights, so to achieve the desired thickness of the encapsulating layer. This will enable the PCB manufacturer to achieve a certain level of dielectric resistance between neighboring components or to meet certain functional or competitive requirements, such as shock protection, moisture protection, or protection of trade secrets from reverse engineering investigations. Therefore, the selective encapsulation of pre-determined portions of the board according to the first embodiment provides for encapsulating layers of greater uniformity than the prior art, and, hence, for a reduced use of resin, because of the lesser need to compensate the inherent inconsistencies of prior encapsulation processes by dispensing more resin.

In the fourth step, the board is transferred to a curing station, generally an oven, where the dam and fill resins are cured. Due to the reduced thicknesses of the encapsulating layers made possible by the method in the first embodiment, and by the appropriate selection of the dam and fill resins employed, a relatively low curing temperature and a relatively short curing cycle may be employed. More specifically, for the -18 and -13 resins, a curing cycle of 95-110 C for approximately 20 minutes was employed.

One skilled in the art will recognize that different variations of the first embodiment are possible, which yet fall within the scope of the present invention. For instance, if automated dispensing equipment is used, the dispensing nozzle may be heated to increase resin flow and process yields, or different combinations of curing temperature and time may be devised to meet the requirements of specific manufacturing environments. Further, vacuum may be applied after dispensing the dam and fill resins, in order to minimize pinhole formation, although certain mono-component resins, such as the -18 and -13 resins, may not require the application of vacuum during the encapsulation process. Still further, a dam may not be provided, and one or more electronic components, or portions thereof, may be coated with an un-dammed fill resin, if the fill resin is of sufficient viscosity to avoid undesired runoffs, or a sufficiently wide tolerance on the perimeter of the coated area is provided to justify the savings associated with the removal of the damming step.

In summary, the practice of the first embodiment provides for higher process yields than possible in the prior art, because process cycles are shortened and resins are applied at room temperature.

Further, components or sections thereof may be encapsulated within precise perimeters, and tall components may be encapsulated through multi-level depositions of resin, thereby achieving a targeted protection of certain portions of the PCB and reduced material costs compared to the prior art.

Still further, the practice of the present invention reduces the exposure to heat of the PCB and the related, potential damages, such as component degradation, board degradation, and thermal shock.

Yet further, because selective, targeted encapsulations of certain electronic components are now possible, the circuit designer can reduce the distance between components of different voltages and achieve higher board densities. F or instance, the -13 resin has a nominal dielectric rating of 17,700 V/mm (450 V/mil). If the voltage differential between two components is 10,000 V, without encapsulation a spacing of at least 25 mm (1 in) is required between the two components. Instead, by the practice of the first embodiment, a selective encapsulation of only 0.6 mm (22 mil) achieves the same level of electrical insulation on a nominal basis, thereby enabling the designer to increase the density of high voltage components on a PCB.

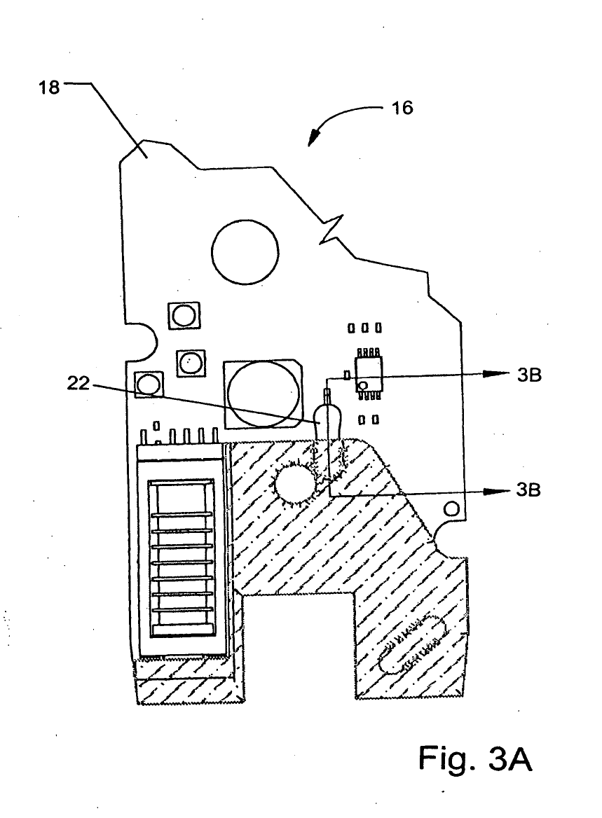

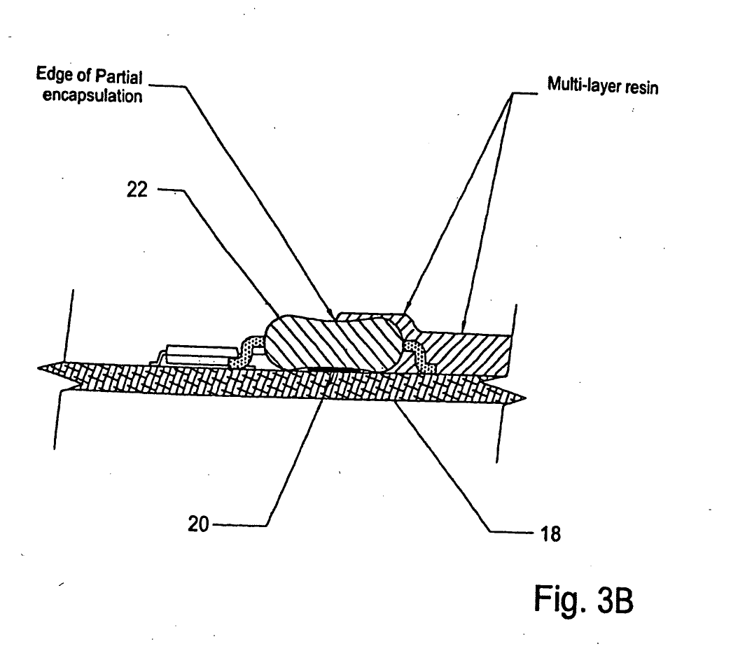

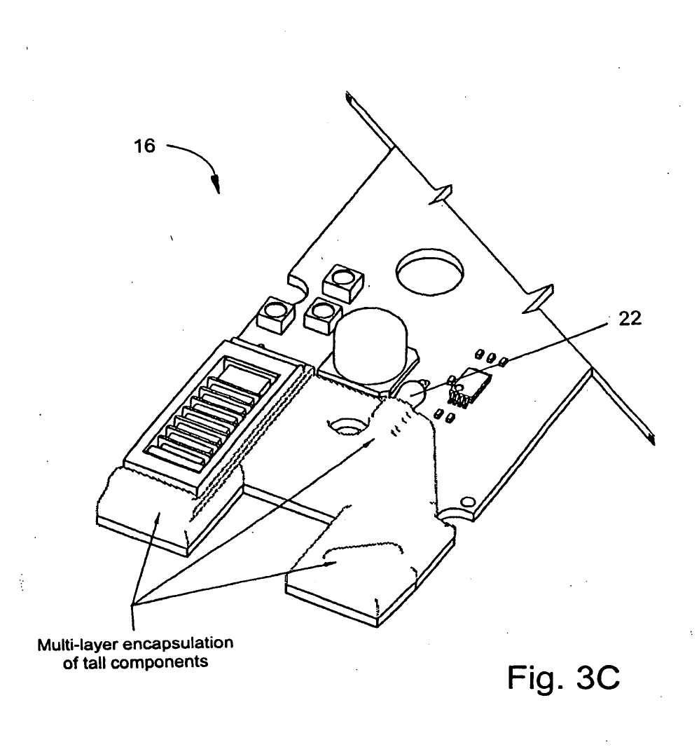

Turning now to FIGS. 3A, 3B, and 3C, there is shown the practice of a second embodiment of the invention, wherein the selective encapsulation process includes the creation of a primary dielectric barrier between a component and the substrate prior to dispensing the dam and fill resins. More particularly, FIGS. 3A and 3C show different views of a portion of a PCB 16 where a selective encapsulation has been applied in accordance with the second embodiment of the invention, while FIG. 3B illustrates with greater specificity the creation of the primary dielectric barrier.

In the second embodiment, a substrate 18 is delivered to an encapsulating nest at room temperature, and a resin bead 20, such as an epoxy bead, is laid in a position preferably transverse in relation to a target electronic component 22, for instance, in a direction that is perpendicular to component 22 and preferably bisects a line drawn between the PCB contact pads or 10 through-holes. One skilled in the art will recognize that the size of bead 20 will be determined according to the size of the component to be placed.

The resin beads not only act as primary dielectric barriers, but also aid component retention during assembly. As an additional benefit, the beads further reduce potential entrapments of gases within the fill resin.

After bead deposition and component placement, the components are soldered, and the components are encapsulated as in the first embodiment.

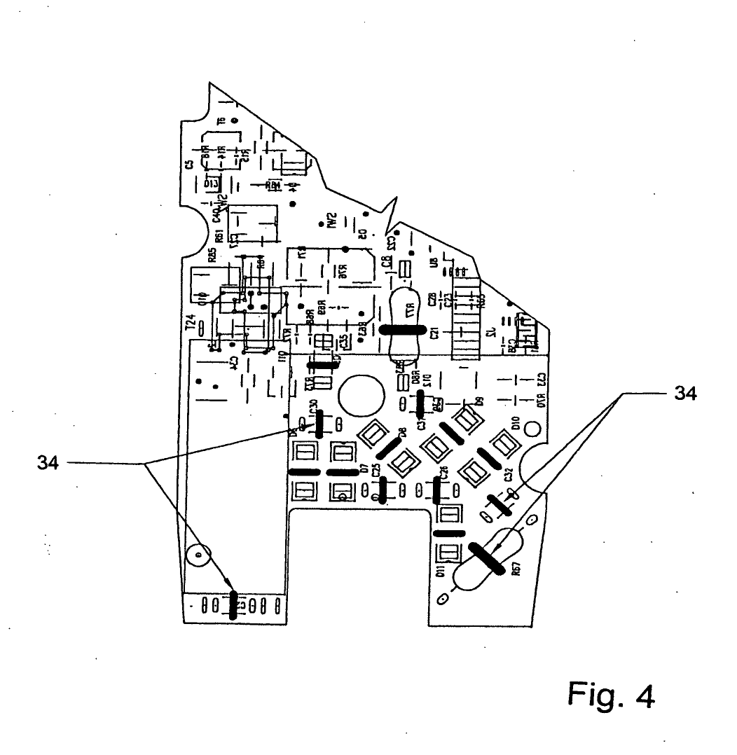

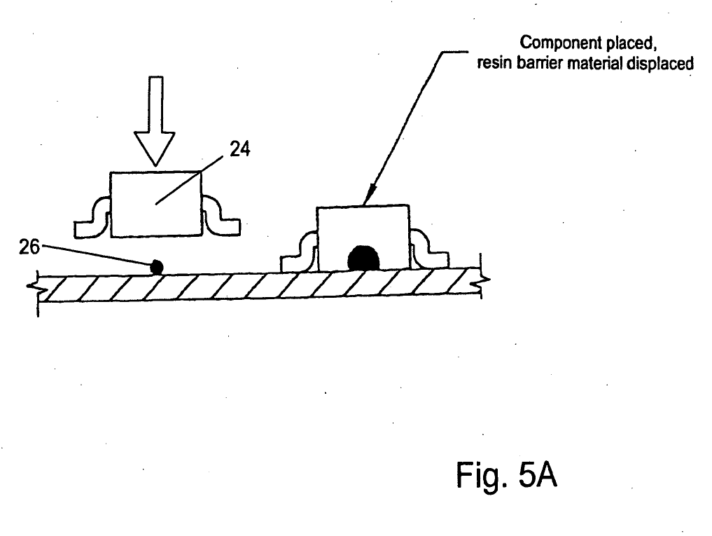

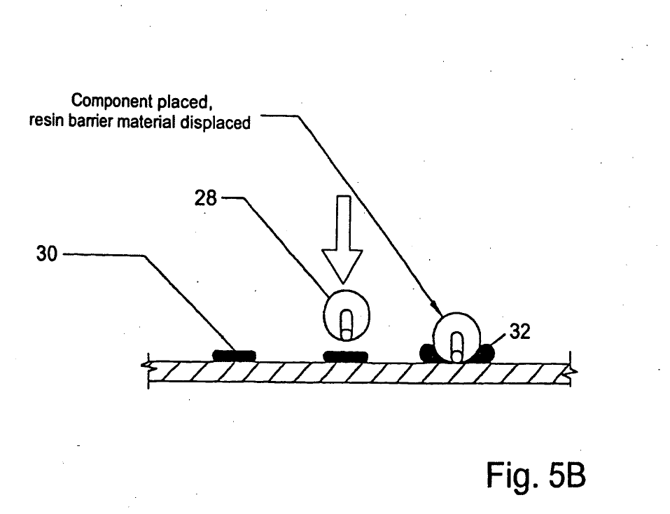

Turning now to FIGS. 4, 5A, and 5B, there is shown the practice of the second embodiment of the invention in relation to different types of electronic components. As shown in FIGS. 5A and SB, during component placement, the resin bead is deformed by the pressure of the applied component. More specifically, as shown in FIG. 5A, a component 24 with a contact surface that is essentially planar will fully compress a bead 26 in the area of contact, creating an adhesive layer and causing the bead to bulge in the non-contact area. Instead, as shown in FIG. 5B, a component 28 with a bottom surface that is essentially convex will cause a bead 30 to deform to a cradle shape 32, within which component 28 will be retained in place during the subsequent steps of the second embodiment. A plurality of beads 34 may be applied to the substrate, as illustrated in FIG. 4.

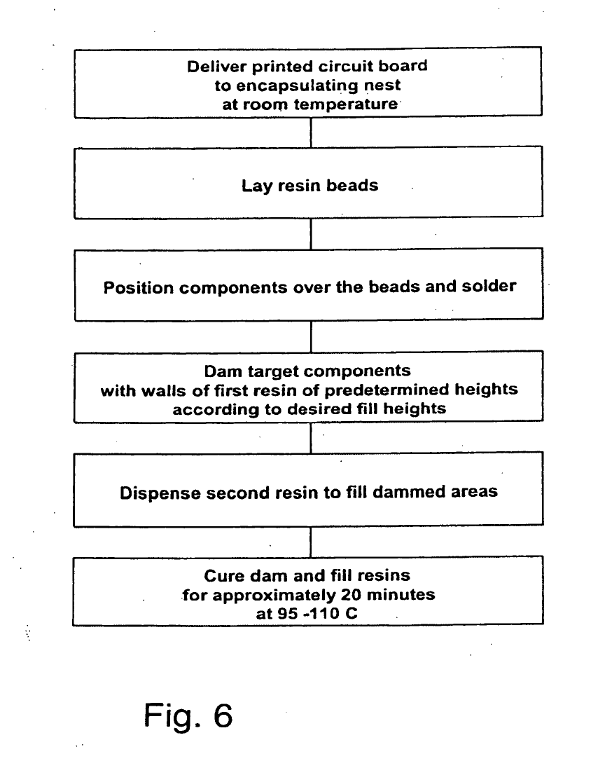

Finally, there is shown in FIG. 6 a flow chart summarizing the different steps of the second embodiment. A person skilled in the art will recognize that different variations of the second embodiment will still be comprised within its scope. For instance, the first, third, fourth, and fifth steps of the second embodiment may be varied in like manner as the corresponding steps of the first embodiment; and the deposition of the resin bead in the second step may be performed at different angles in relation to the target component, according to individual design preferences or manufacturing requirements.

A person skilled in the art will also recognize that the method for the encapsulation of an electronic component on a PCB by the use of resin beads positioned between the electronic component and the PCB substrate can be extended to encapsulation methods that provide for the use of any types of resins, not only of resins comprising latent curing agents and, more specifically, of resins employed in a room temperature environment.

Although these techniques and structures have been disclosed in the context of certain embodiments and examples, it will be understood by those skilled in the art that these techniques and structures may be extended beyond the specifically disclosed embodiments to other embodiments and/or uses and obvious modifications and equivalents thereof. Thus, it is intended that the scope of the structures and methods disclosed herein should not be limited by the particular disclosed embodiments described above.

The present invention is particularly suited for the physical protection and the electrical insulation of high voltage integrated circuits.

By the practice of the present invention, a narrower component spacing on high voltage circuit boards may be achieved than in the prior art, thereby enabling a closer spacing of high voltage components. Further, process times are shortened and certain heating cycles are eliminated, thereby reducing manufacturing costs, increasing production throughputs, and reducing thermal degradation of the PCB.

1. A method for the selective encapsulation of one or more electronic components on a printed circuit board (PCB) comprising the steps of:
(a) delivering said PCB to an encapsulating station in a room temperature environment;
(b) coating a fill resin over at least a portion of said one or more electronic components, wherein said fill resin comprises a first latent curing agent, and wherein said fill resin is dispensed at substantially room temperature; and
(c) subjecting said PCB to a heating and pressure cycle suitable for reticulating said fill resin to a solid state.
